(19) United States
(12) Patent Application Publication
(10) Pub. No.: US 2018/0277360 A1
(43) Pub. Date: Sep. 27, 2018

(54) Method and Composition for Providing Pore Sealing Layer on Porous Low Dielectric Constant Films

(71) Applicant: Versum Materials US, LLC, Tempe, AZ (US)

(72) Inventors: Jianheng Li, Santa Clara, CA (US); Raymond Nicholas Vrtis, Tempe, AZ (US); Robert Gordon Ridgeway, Tempe, AZ (US); Xinjian Lei, Carlsbad, CA (US); Mark Leonard O'Neill, Tempe, AZ (US); Xuezhong Jiang, San Marcos, CA (US)

(73) Assignee: Versum Materials US, LLC, Temper, AZ (US)

(21) Appl. No.: 15/954,906

(22) Filed: Apr. 17, 2018

Related U.S. Application Data
(62) Division of application No. 14/820,982, filed on Aug. 7, 2015, now abandoned.
(60) Provisional application No. 62/037,392, filed on Aug. 14, 2014.

(51) Int. Cl. H01L 21/02; H01L 21/768; H01L 21/3105; C23C 16/40; C23C 16/455

(52) U.S. Cl. CPC H01L 21/02126; H01L 21/76831; H01L 21/76829; H01L 21/76826; H01L 21/3105; H01L 21/0228; H01L 21/02274; H01L 21/02216; H01L 21/02214; H01L 21/02211; C23C 16/45553; C23C 16/45542; C23C 16/401

(57) ABSTRACT

Described herein is a method and composition comprising same for sealing the pores of a porous low dielectric constant (“low k”) layer by providing an additional thin dielectric film, referred to herein as a pore sealing layer, on at least a surface of the porous, low k layer to prevent further loss of dielectric constant of the underlying layer. In one aspect, the method comprises: contacting a porous low dielectric constant film with at least one organosilicon compound to provide an absorbed organosilicon compound and treating the absorbed organosilicon compound with ultraviolet light, plasma, or both, and repeating until a desired thickness of the pore sealing layer is formed.

### CROSS-REFERENCE OF RELATED APPLICATIONS

This application is a divisional of U.S. patent application Ser. No. 14/820,982 filed Aug. 7, 2015, which, in turn, claims priority to, and the benefit of, U.S. provisional application Ser. No. 62/037,392, filed Aug. 14, 2014, which is incorporated herein by reference in its entirety.

### BACKGROUND OF THE INVENTION

Described herein is a method and composition comprising same for sealing the pores of a porous low dielectric constant (“low k”) layer by providing an additional thin dielectric film, referred to herein as a pore-sealing layer, on at least a surface of the porous, low k layer to prevent further loss of dielectric constant of the underlying layer.

One of the challenges facing integrated circuit (IC) manufacturers today is the integration of porous, low dielectric constant (“low k”) materials with atomic layer deposition (ALD) or physical vapor deposition (PVD) metal films such as, but not limited to, copper, cobalt, or other metals or alloys thereof, at narrow device geometries. As the dielectric constants of the low k films or layers decrease below, for example, about 2.5, the percent porosity of these films is at about 30% or greater. As the porosity levels within these films increase, the pores begin to become more interconnected due to the shear number of pores in the film.

When these porous low k films are integrated, the films are typically first patterned using a photoresist and a reactive ion etching (RIE) plasma etch step using a fluorocarbon and oxygen with an optional hydrofluorocarbon. After the via and trenches are formed, the remaining photoresist is removed in a plasma ash step, which is generally either a hydrogen or oxygen plasma. Optionally, ammonia (NH₃) can be used in place of the hydrogen (H₂) or carbon dioxide (CO₂) can be used in place of oxygen (O₂). Typical porous low k films are comprised of porous organosilicate (OSG). During either the etch step, the ash step, or both, the porous OSG films are typically damaged in a manner in which the methyl groups bonded to Si in the film, or the Si-Me groups, near the surface are removed by reaction with neutral radicals diffusion into the porous films. In certain instances, the Si-Me groups forms Si—OH which negatively impacts the hydrophobicity of the film. After the photoresist is removed, the barrier nitride on top of the metal film at the bottom of the via is typically removed in a “punch through” step to quickly remove the SiCN barrier nitride and expose the metal layer.

Typically, the next step is to deposit a barrier or a barrier layer to prevent metal diffusion in the feature. An example of a barrier layer having a tantalum nitride (TaN) layer with a metallic tantalum (Ta) layer deposited upon the TaN layer. Although both the TaN and Ta layers were deposited by physical vapor deposition (PVD) or sputtering, with shrinking feature sizes and the demand for thinner barriers such as copper, there has been a shift from PVD TaN to atomic layer deposition (ALD) TaN. The increased interconnectedness of the pores in the OSG films along with the plasma damage results in diffusion of the metal precursors used to deposit ALD copper barriers such as, pentakis(dimethylamino)tantalum, Ta(NMe₂)₅, used for ALD Tantalum nitride, into the porous low k dielectric film, which adversely affects insulating properties of the film. In order to prevent the metal-containing precursor(s) from diffusing into the porous OSG during ALD, it is desirable to seal the surface of the porous OSG film before the ALD process. However, due to the narrowness of the trenches and vias features where the pores are exposed (e.g., trench width less than 20 nm), it is desirable that this pore sealing layer occupies as little space as possible. It would be also advantageous if the pore sealing occurred inside the pores at or near the surface of the porous low k, such as the OSG layer, such that there was minimum pore sealing layer grown on top of the porous low k film, thus minimizing the loss of trench/via width.

U. S. Publ. No. 2013/0337583 describes a method for repairing process related damage of a dielectric constant film that includes (i) adsorbing a first gas containing silicon on the surface of the damaged dielectric film without depositing a film in the absence of reactive species; (ii) adsorbing a second gas containing silicon on the surface of the damaged dielectric film followed by applying a reactive species to the surface of the film to form a monolayer thereon, and (iii) repeating step (ii). The duration of the exposing the surface in step (i) is longer than the duration of exposing the surface to the second gas in step (ii).

U.S. Pat. No. 8,236,684 describes a method and apparatus for treating a porous dielectric layer which is capped by a dense dielectric layer. The dielectric layers are patterned and dense dielectric layer is depositing conformally over the substrate. The dense conformal dielectric layer seals the pores of the porous dielectric layer against contact from species that may infiltrate the pores.

U. S. Publ. No. 2014/0004717 describes a method for repairing and lowering the dielectric constant of low-k dielectric layer by exposing the porous low-k dielectric layer to a vinyl silane containing compound and optionally exposing the porous low-k dielectric layer to an ultraviolet (U/V) cure process.

There are a number of challenges to overcome in developing a method to seal pores in the porous low k layer. First, because the metal (e.g., copper, cobalt, other metals, or alloys thereof) layer at the bottom of the via is exposed to the pore-sealing process, oxidizing environments should be avoided during the deposition of the pore sealing layer. Second, it is desirable to selectively deposit the pore sealing layer on/in the porous low k layer while not depositing a layer atop of the metal, which is a challenge with current processes. Lastly, since the pores of the low k material are to be sealed, the pore sealing material has to be selected so as to maintain the dielectric constant of the layer or, at the minimum, not significantly raise the dielectric constant such that the dielectric constant of the porous low k layer (having the pore sealing layer deposited thereupon or a sealed porous low k layer) remains 3.0 or less, or 2.9 or less, or 2.7 or less, or 2.5 or less, or 2.4 or less, or 2.3 or less, or 2.2 or less, or 2.1 or less. Accordingly, there remains a need for a process to seal pores in a via in a patterned, porous low k layer, such as without limitation a porous OSG layer, that addresses one or more of these challenges.

### SUMMARY OF THE INVENTION

The present invention satisfies one or more needs described above by providing a thin dielectric film, or a pore sealing layer, which seals the damaged pores of the underlying porous low k film and wherein the pore sealing layer provides one or more of the following: (a) prevents diffusion of the barrier metal into the porous low k film as measured by compositional analysis of the porous low k film; (b) minimizes the dielectric constant change of the underlying porous low k film, i.e. the difference between the dielectric constant for the porous low k film, before the pore sealing layer is deposited thereupon and the dielectric constant after the pore sealing layer is deposited thereupon, is 0.5 or less, 0.4 or less, 0.3 or less, 0.2 or less, 0.1 or less; and (c) selectively deposits on the porous low k film relative to the metal (such as copper, cobalt, or other metal or alloys thereof) layer, i.e. the deposition rate of the pore sealing layer on the porous low k film compared to the deposition rate of the pore sealing layer on the metal or copper layer is about 8 to about 10 times greater, or about 5 to about 8 times greater, or about 2 to about 5 times greater.

In one aspect, there is provided a method for forming a pore sealing layer comprising the steps of:
a. providing a substrate having a porous low dielectric constant layer in a reactor;
b. contacting the substrate with at least one organosilicon compound having the structure of Formulae E:

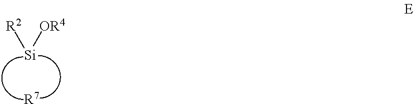

wherein R² is selected from the group consisting of a hydrogen atom, a C₁ to C₁₀ linear alkyl group, a C₃ to C₁₀ branched alkyl group, a C₃ to C₁₀ cyclic alkyl group, a C₅ to C₁₂ aryl group, a C₂ to C₁₀ linear or branched alkenyl group, and a C₂ to C₁₀ linear or branched alkynyl group; R⁴ is selected from the group consisting of a C₁ to C₁₀ linear alkyl group, a C₃ to C₁₀ branched alkyl group, a C₃ to C₁₀ cyclic alkyl group, a C₃ to C₁₀ linear or branched alkenyl group, a C₃ to C₁₀ linear or branched alkynyl group, and a C₅-C₁₂ aryl group; and R⁷ is a C₃ to C₁₀ alkyl di-radical which forms a four-membered, five-membered, or six-membered cyclic ring with the Si atom, to provide an absorbed organosilicon compound on at least a portion of a surface of the porous low dielectric constant layer;

c. purging the reactor with a purge gas;

d. introducing a plasma into the reactor to react with absorbed organosilicon compound, and

e. purging the reactor with a purge gas,

wherein steps b through e are repeated until a desired thickness of the pore sealing layer is formed on the surface and provides a sealed dielectric constant layer. In certain embodiments, the porous low dielectric constant layer has a first dielectric constant and the sealed low dielectric constant layer has a second dielectric constant and the difference between the first dielectric constant and the second dielectric constant is 0.5 or less. In this or other embodiments, the porous low dielectric constant layer further comprises metal and wherein a first deposition rate of the pore sealing layer on the porous low dielectric film compared to a second deposition rate of the pore sealing layer on the metal is from 2 times greater to 10 times greater.

### BRIEF DESCRIPTION OF THE DRAWINGS

FIGS. 1(a) and (b) provide transmission electron microscopy (TEM) images of the sidewall of a patterned wafer comprising a porous low k dielectric film that was coated with a pore sealing layer in accordance with the method described in Example 1. FIGS. 1(a) and (b) show a clear interface between the Ta₂O₅ layer and porous low k dielectric layer which indicates a good pore-sealing effect of the pore sealing layer.

FIGS. 2(a), 2(b), and 2(c) provide energy dispersive X-ray spectroscopy (EDX) images obtained from the sidewall of a patterned wafer that was coated with a pore sealing layer deposited using the organosilicon compound trimethoxymethylsilane and a Ta₂O₅ layer deposited using pentakis(dimethylamino)tantalum, as described in Example 1. No Ta was detected in the porous low k dielectric layer.

### DETAILED DESCRIPTION

Described herein is a composition and method using same wherein exposed SiOH groups, contained within a porous, low dielectric constant (low k) or organosilicate glass (OSG) film or layer, that remain on the film from one or more of the following manufacturing processes: etching, ash, planarization and/or combinations thereof, are used as an anchor for the plasma enhanced atomic layer deposition (ALD) of a pore sealing film or layer. Exemplary low k OSG films are deposited by a chemical vapor deposition (CVD) process using the silicon-containing precursor diethoxymethylsilane, such as the DEMS® precursor provided by Air Products and Chemicals, and a porogen precursor which is subsequently removed from the low k film using a thermal anneal, a ultraviolet cure (UV) step, or a combination thereof. The term “low dielectric constant film” or “low k film” means a low k film such as a porous OSG film that has a dielectric constant of 3.0 or less, or 2.7 or less, or 2.5 or less, or 2.3 or less. In certain embodiments, the porous low k film or layer comprises a cage and network structure consisting of at least one or more of the following bonds: Si—O, Si—CH₃, and Si-CHx bonds and further comprises pores or voids. In this or other embodiments, the low k films described herein further contain at least 15% or greater, at least 20% or greater, at least 25% or greater, or at least 30% or greater percent porosity as measured by ellipsometric porosimetry. The term “damaged porous low dielectric film” or “damaged low k film” means a low k film such as a porous OSG film that was subjected to one or more of the following manufacturing processes: etching, ash, planarization and/or combinations thereof.

In the method, a substrate having a damaged porous low k layer is placed into a reactor or deposition chamber. Then, at least a portion of the surface of a damaged porous low k dielectric layer, such as the horizontal surface of, for example, an etched via, is contacted with an organosilicon compound comprised of at least one selected from the group consisting having one or more following formulae A through G described herein to provide an absorbed organosilicon layer upon at a portion of the surface. Next, the low k porous layer is treated with at least one selected from ultraviolet (UV) light, a plasma comprising at least one selected from plasma comprising at least one selected from nitrogen (N₂), argon (Ar), helium (He), hydrogen (H), ammonia (NH₃), and combination(s), or both. The contacting and treating processing steps are repeated until a desired thickness of a pore sealing layer is formed on at least a portion of the surface the porous low k layer. As a result, the open pore(s) in the porous low k layer are sealed. Exemplary deposition methods, for forming the pore sealing layer on at least a portion of the surface of the porous low k dielectric layer include, without limitation, plasma enhanced atomic layer deposition process (PEALD), plasma enhanced cyclic chemical vapor deposition (PECCVD), and a plasma enhanced ALD-like process

In other embodiments of the present invention, the surface of the low k layer is treated with an organosilicon compound having at least one alkoxy group having the formula A:

(R⁴O)₃₋ₘSiR²R³ₘ A

wherein R² and R³ are each independently selected from a hydrogen atom, a C₁ to C₁₀ linear alkyl group, a C₃ to C₁₀ branched alkyl group, a C₃ to C₁₀ cyclic alkyl group, a C₅ to C₁₂ aryl group, a C₂ to C₁₀ linear or branched alkenyl group, and a C₂ to C₁₀ linear or branched alkynyl group; R⁴ is selected from a C₁ to C₁₀ linear alkyl group, a C₃ to C₁₀ branched alkyl group, a C₃ to C₁₀ cyclic alkyl group, a C₃ to C₁₀ linear or branched alkenyl group, and a C₃ to C₁₀ linear or branched alkynyl group, a C₅-C₁₂ aryl group and wherein m=0, 1, or 2. Exemplary compounds having formula A include, but are not limited to, trimethoxymethylsilane, dimethoxydimethylsilane, triethoxymethylsilane, diethoxydimethylsilane, trimethoxysilane, dimethoxymethylsilane, di-isopropyldimethoxysilane, diethoxymethylsilane, dimethoxyvinylmethylsilane, dimethoxydivinylsilane, diethoxyvinylmethylsilane, and diethoxydivinylsilane. In embodiments wherein the damaged, porous low k film is contacted with the formula A organosilicon compound to form an absorbed organosilicon compound on at least a portion of the surface of the porous low k film, the substrate is then treated with a plasma comprising at least one selected from the group consisting of argon (Ar), helium (He), hydrogen (H), or combination(s) thereof plasmas which is introduced into the reactor to promote further reaction and form more Si—O—Si linkages. The process steps, of contacting the organosilicon compound with at least a portion of the surface of the porous low k layer and treating with plasma, are repeated until a desired thickness of the pore sealing layer is obtained. As a result, the open pore(s) in the underlying porous low k layer are sealed to provide a sealed porous low dielectric constant or porous low k layer.

The following scheme 1 provides an embodiment of the process described herein wherein at least a portion of the surface of a porous low k layer is contacted with an organosilicon compound having formula A wherein R² is a vinyl group to anchor the vinyl-containing silicon fragments on the surface via reaction of the organoamino groups of the organosilicon compound with Si—OH and provide absorbed organosilicon compound. The surface is then treated, with ultraviolet light, a plasma comprised of argon (Ar), helium (He), hydrogen (H), or combination(s), or both, to activate the reaction between the anchored vinyl-containing silicon fragments with Si—H and create at least one Si—CH₂CH₂—Si linkage with ultraviolet light (UV) and/or plasma. The process steps, of contacting the organosilicon compound with at least a portion of the surface of a porous low k layer and treating with UV, plasma, or both, are repeated until a desired thickness of the pore sealing layer is formed. As a result, the open pore in the low k layer is sealed to provide a sealed porous low dielectric constant or porous low k layer.

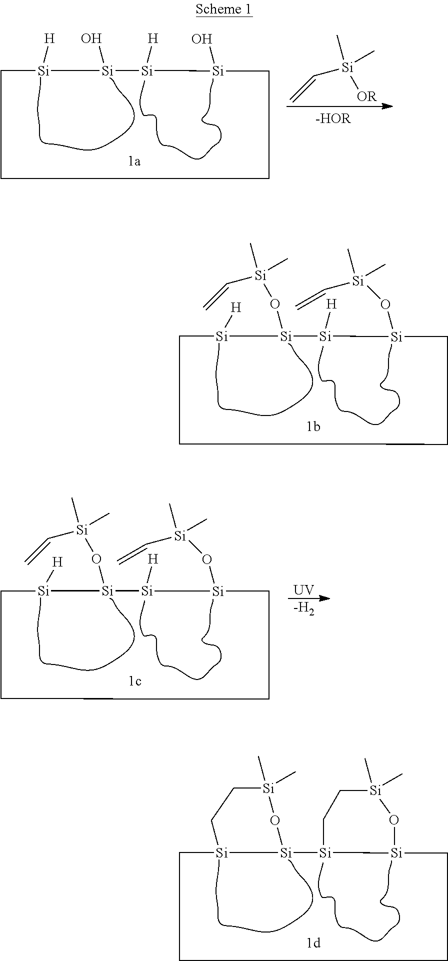

In another embodiment of the method described herein, the porous low k layer is contacted with an organosilicon compound having the following formula B which has at least one alkoxy group and a Si—O—Si linkage:

(R⁴O)₃₋ₙR²ₙSi—O—SiR²ₙ(OR⁴)₃₋ₙ B

wherein R² is selected from a hydrogen atom, a C₁ to C₁₀ linear alkyl group, a C₃ to C₁₀ branched alkyl group, a C₃ to C₁₀ cyclic alkyl group, a C₅ to C₁₂ aryl group, a C₂ to C₁₀ linear or branched alkenyl group, and a C₂ to C₁₀ linear or branched alkynyl group; R⁴ is selected from a C₁ to C₁₀ linear alkyl group, a C₃ to C₁₀ branched alkyl group, a C₃ to C₁₀ cyclic alkyl group, a C₃ to C₁₀ linear or branched alkenyl group, and a C₃ to C₁₀ linear or branched alkynyl group, a C₅-C₁₂ aryl group and wherein n=0, 1, or 2 to provide an absorbed organosilicon compound on at least a portion of the surface. Exemplary compounds having formula B include, but are not limited to, 1,1,3,3-tetramethoxy-1,3-dimethyldisiloxane, 1,1,3,3-tetraethoxy-1,3-dimethyldisiloxane, 1,3-dimethoxy-1,1,3,3-tetramethyldisiloxane, and 1,3-diethoxy-1,1,3,3-tetramethyldisiloxane. The substrate is then treated with UV, a plasma comprising at least one selected from the group consisting of argon (Ar), helium (He), hydrogen (H), or combination(s) thereof, or both, which is introduced into the reactor to promote further reaction and form more Si—O—Si linkages. The process of contacting the organosilicon compound with the surface of a porous low k layer and treatment with ultraviolet light (UV) and/or a plasma, are repeated until a desired thickness of a pore sealing layer is obtained. As a result, the open pore(s) in the underlying porous low k layer are sealed to provide a sealed porous low dielectric constant or porous low k layer.

In another embodiment of the method described herein, the porous low k layer is contacted with an organosilicon compound having at least one carboxylic group as shown in the following formula C:

(R⁴COO)₃₋ₘSiR²R³ₘ C

wherein R² and R³ are each independently selected from a hydrogen atom, a C₁ to C₁₀ linear alkyl group, a C₃ to C₁₀ branched alkyl group, a C₃ to C₁₀ cyclic alkyl group, a C₅ to C₁₂ aryl group, a C₂ to C₁₀ linear or branched alkenyl group, and a C₂ to C₁₀ linear or branched alkynyl group; R⁴ is selected from a C₁ to C₁₀ linear alkyl group, a C₃ to C₁₀ branched alkyl group, a C₃ to C₁₀ cyclic alkyl group, a C₃ to C₁₀ linear or branched alkenyl group, a C₃ to C₁₀ linear or branched alkynyl group, and a C₅-C₁₂ aryl group and wherein m=0, 1, or 2. Exemplary compounds having formula C include, but are not limited to, dimethyldiacetoxysilane and methyltriacetoxysilane. The substrate is then treated with UV, a plasma comprising at least one selected from the group consisting of argon (Ar), helium (He), hydrogen (H), or combination(s) thereof, or both, which is introduced into the reactor to promote further reaction and form more Si—O—Si linkages. The process of contacting the organosilicon compound with the surface of a porous low k layer and treatment with ultraviolet light (UV) and/or a plasma, are repeated until a desired thickness of a pore sealing layer is obtained. As a result, the open pore(s) in the underlying porous low k layer are sealed.

In another embodiment of the method described herein, the porous low k layer is contacted with an organosilicon compound having at least one carboxylic group having a Si—O—Si linkage as shown in the following formula D:

(R⁴COO)₃₋ₙR²ₙSi—O—SiR²ₙ(OOCR⁴)₃₋ₙ D

wherein R² and R³ are selected from a hydrogen atom, a C₁ to C₁₀ linear alkyl group, a C₃ to C₁₀ branched alkyl group, a C₃ to C₁₀ cyclic alkyl group, a C₅ to C₁₂ aryl group, a C₂ to C₁₀ linear or branched alkenyl group, and a C₂ to C₁₀ linear or branched alkynyl group; R⁴ is selected from a C₁ to C₁₀ linear alkyl group, a C₃ to C₁₀ branched alkyl group; a C₃ to C₁₀ cyclic alkyl group, a C₃ to C₁₀ linear or branched alkenyl group, and a C₃ to C₁₀ linear or branched alkynyl group, a C₅-C₁₂ aryl group and wherein n=0, 1 or 2. Exemplary compounds having formula D include, but are not limited to, 1,1,3,3-tetraacetoxy-1,3-dimethyldisiloxane and 1,3-tetraacetoxy-1,1,3,3-tetramethyldisiloxane. The substrate is then treated with UV, a plasma comprising at least one selected from the group consisting of argon (Ar), helium (He), hydrogen (H), or combination(s) thereof, or both, which is introduced into the reactor to promote further reaction and form more Si—O—Si linkages. The process of contacting the organosilicon compound with the surface of a porous low k layer and treatment with ultraviolet light (UV) and/or a plasma, are repeated until a desired thickness of a pore sealing layer is obtained. As a result, the open pore(s) in the underlying porous low k layer are sealed.

In another embodiment of the method described herein, the porous low k layer is contacted with an organosilicon compound having at least one alkoxy group as shown in the following formula E:

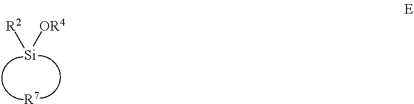

wherein R² is selected from a hydrogen atom, a C₁ to C₁₀ linear alkyl group, a C₃ to C₁₀ branched alkyl group, a C₃ to C₁₀ cyclic alkyl group, a C₅ to C₁₂ aryl group, a C₂ to C₁₀ linear or branched alkenyl group, and a C₂ to C₁₀ linear or branched alkynyl group; R⁴ is selected from a C₁ to C₁₀ linear alkyl group, a C₃ to C₁₀ branched alkyl group, a C₃ to C₁₀ cyclic alkyl group, a C₃ to C₁₀ linear or branched alkenyl group, a C₃ to C₁₀ linear or branched alkynyl group, and a C₅-C₁₂ aryl group; R⁷ is selected from a C₂ to C₁₀ alkyl di-radical which forms a four-membered, five-membered, or six-membered cyclic ring with the Si atom. In one particular embodiment of formula E, R² is selected from a hydrogen, a methyl group, or a ethyl group whereas R⁴ is selected from a methyl group, an ethyl group, a propyl group, and a butyl group. Exemplary compounds having formula E include, but are not limited to, 1-methyl-1-methoxy-1-silacyclopentane, 1-methyl-1-ethoxy-1-silacyclopentane, 1-methyl-1-iso-propoxy-1-silacyclopentane, 1-methyl-1-n-propoxy-1-silacyclopentane, 1-methyl-1-n-butoxy-1-silacyclopentane, 1-methyl-1-sec-butoxy-1-silacyclopentane, 1-methyl-1-iso-butoxy-1-silacyclopentane, 1-methyl-1-tert-butoxy-1-silacyclopentane, 1-methoxy-1-silacyclopentane, 1-ethoxy-1-silacyclopentane, 1-methyl-1-methoxy-1-silacyclobutane, 1-methyl-1-ethoxy-1-silacyclobutane, 1-methoxy-1-silacyclobutane, and 1-ethoxy-1-silacyclobutane. The substrate is then treated with UV, a plasma comprising at least one selected from the group consisting of argon (Ar), helium (He), hydrogen (H), or combination(s) thereof, or both, which is introduced into the reactor to promote further reaction and form more Si—O—Si linkages. The process of contacting the organosilicon compound with the surface of a porous low k layer and treatment with ultraviolet light (UV) and/or a plasma, are repeated until a desired thickness of a pore sealing layer is obtained. As a result, the open pore(s) in the underlying porous low k layer are sealed.

In another embodiment of the method described herein, the porous low k layer is contacted with an organosilicon compound having at least one alkoxy group as shown in the following formula F:

(R⁴O)₃₋ₙR²ₙSi—R⁵—SiR²ₙ(OR⁴)₃₋ₙ F

wherein R² is independently selected from a hydrogen atom, a C₁ to C₁₀ linear alkyl group, C₃ to C₁₀ branched alkyl group, a C₃ to C₁₀ cyclic alkyl group, a C₅ to C₁₂ aryl group, a C₂ to C₁₀ linear or branched alkenyl group, and a C₂ to C₁₀ linear or branched alkynyl group; R⁴ is selected from a C₁ to C₁₀ linear alkyl group, a C₃ to C₁₀ branched alkyl group, a C₃ to C₁₀ cyclic alkyl group, a C₃ to C₁₀ linear or branched alkenyl group, a C₃ to C₁₀ linear or branched alkynyl group, and a C₅-C₁₂ aryl group, R⁵ is a linear or branched C₁₋₃ alkylene bridge such as, but not limited to, a group containing 1, 2 or 3 carbon atoms, such as without limitation a methylene or an ethylene bridge and wherein n=0, 1 or 2. Exemplary compounds having formula F include, but are not limited to, 1,2-bis(dimethoxymethylsilyl)methane, 1,2-bis(diethoxymethylsilyl)methane, 1,2-bis(dimethoxymethylsilyl)ethane, 1,2-bis(trimethoxysilyl)ethane, and 1,2-bis(diethoxymethylsilyl)ethane.

In another embodiment of the method described herein, the surface of a porous low k dielectric layer is contacted with an organosilicon compound having at least one organoamino anchoring group having the following formula G with a Si—O—Si linkage:

(R³R⁴N)₃₋ₙR²ₙSi—O—SiR²ₙ(NR³R⁴)₃₋ₙ G

wherein R² and R³ are each independently selected a hydrogen atom, a C₁ to C₁₀ linear alkyl group, a C₃ to C₁₀ branched alkyl group, a C₃ to C₁₀ cyclic alkyl group, a C₅ to C₁₂ aryl group, a C₂ to C₁₀ linear or branched alkenyl group, and a C₂ to C₁₀ linear or branched alkynyl group; R⁴ is selected from a C₁ to C₁₀ linear alkyl group, a C₃ to C₁₀ branched alkyl group, a C₃ to C₁₀ cyclic alkyl group, a C₃ to C₁₀ linear or branched alkenyl group, a C₃ to C₁₀ linear or branched alkynyl group, and a C₅-C₁₂ aryl group; and wherein n=0, 1 or 2. Exemplary compounds include having formula G include, but are not limited to, 1,3-dimethylamino-1,1,3,3-tetramethyldisiloxane, 1,3-diethylamino-1,1,3,3-tetramethyldisiloxane, and 1,3-di-sio-propylamino-1,1,3,3-tetramethyldisiloxane. The following Scheme 2 provides an embodiment of the method described herein wherein the damaged porous low k film is contacted with an organosilicon having Formula G and at least one anchoring group which reacts with the exposed Si—OH groups in the damaged porous low k dielectric film to allow the open pore to be sealed.

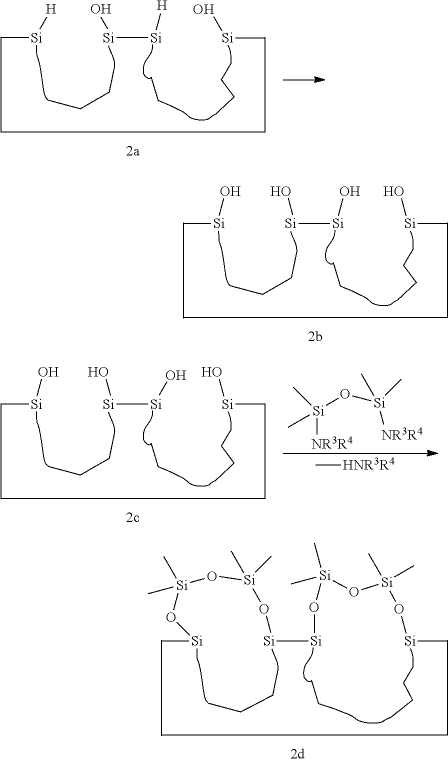

In this or other embodiments, the porous low k dielectric film is treated with UV, a plasma comprised of at least one selected from argon (Ar), helium (He), hydrogen (H), or combination(s) thereof is introduced into the reactor to promote further reaction to form more Si—O—Si linkages. The process steps, of contacting the organosilicon compound with the surface of a low k layer and treating with a plasma, are repeated until a desired thickness of pore sealing layer is formed. As a result, the open pore in the underlying porous low k dielectric film is sealed.

In the formulae described herein and throughout the description, the term “alkyl” denotes a linear or branched functional group having from 1 to 10 or 3 to 10 carbon atoms, respectively. Exemplary linear alkyl groups include, but are not limited to, methyl (Me), ethyl (Et), propyl (n-Pr), butyl (n-Bu), pentyl, and hexyl. Exemplary branched alkyl groups include, but are not limited to, iso-propyl (iso-Pr or ⁱPr), isobutyl (ⁱBu), sec-butyl (^{s}Bu), tert-butyl (^{t}Bu), iso-pentyl, tert-pentyl (amyl), iso-hexyl, and neo-hexyl. In certain embodiments, the alkyl group may be substituted with one or more functional groups such as, but not limited to, an alkoxy group, a dialkylamino group or combinations thereof, attached thereto. In other embodiments, the alkyl group does not have one or more functional groups or hetero atoms attached thereto.

In the formulae described herein and throughout the description, the term “cyclic alkyl” denotes a cyclic functional group having from 3 to 10 or from 4 to 10 carbon atoms or from 5 to 10 carbon atoms. Exemplary cyclic alkyl groups include, but are not limited to, cyclobutyl, cyclopentyl, cyclohexyl, and cyclooctyl groups.

In the formulae described herein and throughout the description, the term “aryl” denotes an aromatic cyclic functional group having from 5 to 12 carbon atoms or from 6 to 10 carbon atoms. Exemplary aryl groups include, but are not limited to, phenyl, benzyl, chlorobenzyl, tolyl, and o-xylyl.

In the formulae described herein and throughout the description, the term “alkenyl group” denotes a group which has one or more carbon-carbon double bonds and has from 2 to 10 or from 3 to 6 or from 3 to 4 carbon atoms.

In the formulae described herein and throughout the description, the term “alkynyl group” denotes a group which has one or more carbon-carbon triple bonds and has from 2 to 10 or from 3 to 6 or from 3 to 4 carbon atoms.

In the formulae described herein and throughout the description, the term “alkoxy group” denotes a group derived from alcohol via removal of a proton. Exemplary alkoxy group include, but are not limited, methoxy, ethoxy, iso-propoxy, n-propoxy, tert-butoxy, sec-butoxy, iso-butoxy.

In the formulae described herein and throughout the description, the term “carboxylic group” denotes a group derived from carboxylic acid via removal of a proton. Exemplary carboxylic group include, but are not limited, acetoxy (MeCOO).

In the formulae described herein and throughout the description, the term “alkylene bridge” denotes a di-radical derived from an alkyl having 1 to 10 carbon atoms, preferably 1 to 4 carbon atoms. Exemplary alkylene bridges include, but are not limited to, —CH₂-(methylene), —CH₂CH₂-(ethylene), —CH(Me)CH₂-(iso-propylene), —CH₂CH₂CH₂-(propylene).

In the formulae described herein and throughout the description, the term “cyclic alkyl” denotes a cyclic functional group having from 3 to 10 or from 4 to 10 carbon atoms or from 5 to 10 carbon atoms. Exemplary cyclic alkyl groups include, but are not limited to, cyclobutyl, cyclopentyl, cyclohexyl, and cyclooctyl groups. In the formulas above and through the description, the term “unsaturated” as used herein means that the functional group, substituent, ring or bridge has one or more carbon double or triple bonds. An example of an unsaturated ring can be, without limitation, an aromatic ring such as a phenyl ring. The term “saturated” means that the functional group, substituent, ring or bridge does not have one or more double or triple bonds.

In certain embodiments, one or more of the alkyl group, alkenyl group, alkynyl group, cyclic group and/or aryl group may be substituted or have one or more atoms or group of atoms such as functional groups substituted in place of, for example, a hydrogen atom. Exemplary substituents include, but are not limited to, oxygen, sulfur, halogen atoms (e.g., F, Cl, I, or Br), nitrogen, and phosphorous. Further exemplary substituents, the alkyl group may have one or more functional groups such as, but not limited to, an alkoxy group, a dialkylamino group or combinations thereof, attached thereto. In other embodiments, one or more of the alkyl group, alkenyl group, alkynyl group, cyclic group and/or aryl group in the formulae described herein does not have one or more functional groups attached thereto.

In the method described above, while not being bound by theory, it is believed that the pore sealing layer selectively deposits on at least a portion of the porous low k dielectric layer vs. metal such as copper, cobalt or alloys thereof, because the molecule is anchored to the film surface due to the reaction with —OH, which does not exist on the surface of metal in the reductive atmosphere. Thus, no deposition can occur on the surface of metal, resulting in good selectivity with respect to the porous low k dielectric layer. For selectivity of deposition of the pore sealing layer onto the porous low k film compared to the metal such as copper, it is preferred the deposition rate of the pore sealing film on the porous low k film relative to metal ranges from one or more of the following end points: about 2 times greater, about 3 times greater, about 4 times greater, about 5 times greater, about 6 times greater, about 7 times greater, about 8 times greater, about 9 times greater, and about 10 times greater. Exemplary ranges include, but are not limited to the following: about 8 to about 10 times greater, or about 5 to about 8 times greater, or about 2 to about 5 times greater. In this or other embodiments, the porous low dielectric constant layer further comprises metal and wherein a first deposition rate of the pore sealing layer on the porous low dielectric film compared to a second deposition rate of the pore sealing layer on the metal portion of the layer is from 2 times greater to 10 times greater.

It is expected that the open pores will be sealed after about 10 to 30 cycles of method described herein. It will be appreciated that the resultant pore sealing layer that is deposited onto the low k dielectric film is relatively thin, or has a thickness of about 5 nanometers (nm) or less, 4 nm or less, 3 nm or less, 2 nm or less, or 1 nm or less, or 0.5 nm or less.

A minimum dielectric constant shift may be necessary for the pore sealing layer to minimize the impact on the electrical performance of the device based on the underlying porous low k dielectric layer. The change for dielectric constant k (i.e. the difference between the dielectric constant for the porous low k film before and after pore sealing layer is applied or the sealed dielectric electric) is 0.5 or less, 0.4 or less, 0.3 or less, 0.2 or less, 0.1 or less. In certain embodiments, the porous low dielectric constant layer has a first dielectric constant and the sealed low dielectric constant layer has a second dielectric constant and the difference between the first dielectric constant and the second dielectric constant is 0.5 or less, 0.4 or less, 0.3 or less, 0.2 or less, 0.1 or less, or 0.05 or less.

The ALD-like process is defined herein as a cyclic CVD process that provides a high conformal pore sealing layer on at least a portion of the porous low k dielectric film. The pore sealing layer can be comprised of silicon-containing film such as amorphous silicon, silicon oxide, carbon doped silicon oxide, silicon carbonitride, silicon nitride. In certain embodiments, the pore sealing layer has a percentage of non-uniformity of 5% or less, a deposition rate of 1 Å or greater per cycle, or both.

The deposition methods described herein may involve one or more purge gases. The purge gas, which is used to purge away unconsumed reactants and/or reaction byproducts, is an inert gas that does not react with the precursors. Exemplary purge gases include, but are not limited to, argon (Ar), nitrogen (N₂), helium (He), neon (Ne), hydrogen (H₂), and mixtures thereof. In certain embodiments, a purge gas such as Ar is supplied into the reactor at a flow rate ranging from about 10 to about 2000 sccm for about 0.1 to 1000 seconds, thereby purging the unreacted material and any byproduct that may remain in the reactor.

Energy is applied to the at least one of the organosilicon compound to induce reaction and to form the pore sealing film or coating on the substrate. Such energy can be provided by, but not limited to, thermal, plasma, pulsed plasma, helicon plasma, high density plasma, inductively coupled plasma, X-ray, e-beam, photon, remote plasma methods, and combinations thereof. In certain embodiments, a secondary RF source can be used to modify the plasma characteristics at the substrate surface. In embodiments wherein the deposition involves plasma, the plasma-generated process may comprise a direct plasma-generated process in which plasma is directly generated in the reactor, or alternatively a remote plasma-generated process in which plasma is generated outside of the reactor and supplied into the reactor.

The organosilicon compounds precursors and/or other silicon-containing precursors may be delivered to the reactor in a variety of ways. In one embodiment, a liquid delivery system may be utilized. In an alternative embodiment, a combined liquid delivery and flash vaporization process unit may be employed, such as, for example, the turbo vaporizer manufactured by MSP Corporation of Shoreview, Minn., to enable low volatility materials to be volumetrically delivered, which leads to reproducible transport and deposition without thermal decomposition of the precursor. In liquid delivery formulations, the precursors described herein may be delivered in neat liquid form, or alternatively, may be employed in solvent formulations or compositions comprising same. Thus, in certain embodiments the precursor formulations may include solvent component(s) of suitable character as may be desirable and advantageous in a given end use application to form a film on a substrate.

In certain embodiments, the method described herein is conducted using a cyclic process on a PECVD/PEALD platform. The silicon wafer susceptor is maintained in at one or more temperatures ranging from about 100 to about 400° C., or about 200 to about 300° C. The liquid organosilicon compound is delivered into the reactor under vacuum at a rate of 50-5000 mg/min (preferably 200˜300 mg/min) with the chamber throttle valve closed. After the liquid flow of compound is turned off, the wafer is allowed to contact the compound or “soak” in the reactor with the precursor vapor at pressures of 1˜8 Torr (preferably 2˜4 Torr). The throttle valve is subsequently opened with inert gas purging for a time ranging from about 10 to about 300 seconds or from about 30 to about 50 seconds. Then, the wafer is treated with UV, a plasma comprising a reactant gas such as N₂, He, Ar, H₂, a plasma comprising an inert gas (He, Ar) in the reactor to activate and react the adsorbed organosilicon precursor while preparing the surface of the growing film for reaction with the next pulse or contact with the organosilicon compound. The power of the plasma in the treatment step ranges from 50 to 3000 W, preferably 200˜300 W with plasma exposure times of 10˜60 seconds (sec.), preferably 15 sec. This sequence of events completes one process cycle, which is repeated 10˜30 times to provide the pore sealing layer.

In one embodiment, there is provided a method of forming a pore sealing layer via plasma enhanced atomic layer deposition process (PEALD), plasma enhanced cyclic chemical vapor deposition (PECCVD) or plasma enhanced ALD-like process. In this embodiment, the method comprises the steps of:

a. providing a substrate having a porous low dielectric constant layer in a reactor;

b. contacting the substrate with at least one organosilicon compound selected from the group consisting of a compound have the following Formulae A through G:

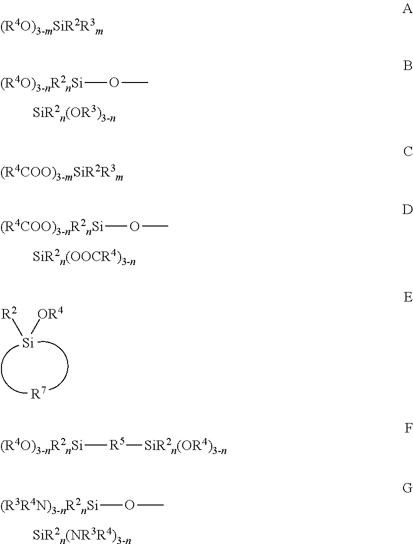

wherein R² and R³ are each independently selected from the group consisting of a hydrogen atom, a C₁ to C₁₀ linear alkyl group, a C₃ to C₁₀ branched alkyl group, a C₃ to C₁₀ cyclic alkyl group, a C₅ to C₁₂ aryl group, a C₂ to C₁₀ linear or branched alkenyl group, and a C₂ to C₁₀ linear or branched alkynyl group; R⁴ is selected from a C₁ to C₁₀ linear alkyl group, a C₃ to C₁₀ branched alkyl group, a C₃ to C₁₀ cyclic alkyl group, a C₃ to C₁₀ linear or branched alkenyl group, a C₃ to C₁₀ linear or branched alkynyl group, and a C₅-C₁₂ aryl group; R⁵ is a linear or branched C₁₋₃ alkylene bridge; and R⁷ is selected from a C₂ to C₁₀ alkyl di-radical which forms a four-membered, five-membered, or six-membered cyclic ring with the Si atom, and wherein m=0, 1, or 2 and n=0, 1 or 2, to provide an absorbed organosilicon compound on at least a portion of a surface of the porous low dielectric constant layer;

c. purging the reactor with a purge gas;

d. introducing a plasma into the reactor to react with absorbed organosilicon compound, and

e. purging the reactor with a purge gas; wherein steps b through e are repeated until a desired thickness of a pore sealing film is formed on the surface.

In yet another aspect, there is provided a method of forming a pore sealing layer via plasma enhanced atomic layer deposition process (PEALD), plasma enhanced cyclic chemical vapor deposition (PECCVD) or plasma enhanced ALD-like process, the method comprising the steps of:

a. providing a substrate having a porous low dielectric constant layer in a reactor;

b. contacting the substrate with at least one organosilicon compound selected from the group consisting of a compound have the following Formulae A through G:

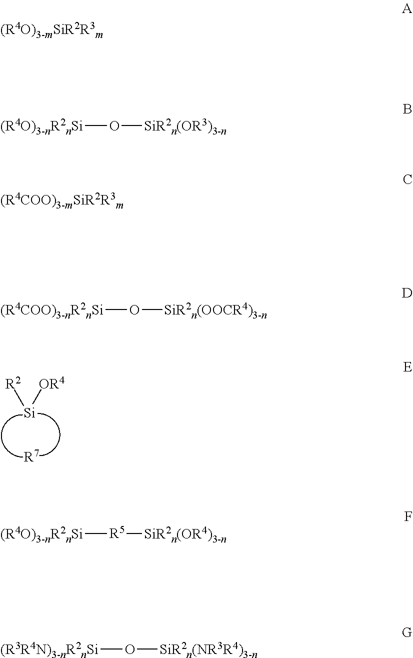

wherein R² and R³ are each independently selected from the group consisting of a hydrogen atom, a C₁ to C₁₀ linear alkyl group, a C₃ to C₁₀ branched alkyl group, a C₃ to C₁₀ cyclic alkyl group, a C₅ to C₁₂ aryl group, a C₂ to C₁₀ linear or branched alkenyl group, and a C₂ to C₁₀ linear or branched alkynyl group; R⁴ is selected from a C₁ to C₁₀ linear alkyl group, a C₃ to C₁₀ branched alkyl group, a C₃ to C₁₀ cyclic alkyl group, a C₃ to C₁₀ linear or branched alkenyl group, a C₃ to C₁₀ linear or branched alkynyl group, and a C₅-C₁₂ aryl group; R⁵ is a linear or branched C₁₋₃ alkylene bridge; and R⁷ is selected from a C₂ to C₁₀ alkyl di-radical which forms a four-membered, five-membered, or six-membered cyclic ring with the Si atom, and wherein m=0, 1, or 2 and n=0, 1 or 2, to provide an absorbed organosilicon compound on at least a portion of a surface of the porous low dielectric constant layer;

c. purging the reactor with a purge gas;

d. introducing a plasma into the reactor to react with absorbed organosilicon compound, and

e. purging the reactor with a purge gas;

f. introducing into the reactor at least one organosilicon compound having Formula A through G wherein the at least one organosilicon compound which differs from the at least one organosilicon in method step b);

g. purging the reactor with a purge gas;

h. introducing a plasma into the reactor to react with absorbed organosilicon compound;

i. purging the reactor with a purge gas, wherein steps b through i are repeated until a desired thickness of the film is obtained. In some embodiment, step b to e are repeated for some cycles before step f. In one particular embodiment, an organosilicon compound having an Si—H bond such as diethoxymethylsilane is used in step b to allow the reduction of copper oxide into copper metal, thus facilitating the selective deposition of the pore sealing layer on the surface of porous low k dielectric layer.

### EXAMPLES

### General Pore Sealing Layer Deposition Experiment and Results

A variety of experiments for depositing different types of pore sealing layers, as well as different deposition conductions, were conducted on 200 millimeter (mm) wafers onto which a layer of a porous diethoxymethylsilane film having a dielectric constant of 2.2 which was deposited from the structure-former diethoxymethylsilane (DEMS) precursor and porogen precursor cyclooctane and ultraviolet (UV) cured as described in US Publ. No.: 2007/0299239.

All the methods for depositing the pore sealing layer were performed on an Applied Materials Precision 5000 system in a 200 mm DXZ chamber fitted with an Astron EX remote plasma generator, using either a silane or a TEOS process kit. The plasma enhanced chemical vapor deposition (PECVD) chamber was equipped with direct liquid injection (DLI) delivery capability. Precursors were liquids at the delivery temperatures and were dependent on the precursor's boiling point. The low-k wafers were damaged to provide a “damaged porous low k dielectric film” with a short NH₃ plasma which removed a portion of the Si-Me groups from the surface of the pores down to a depth of 50 nm to mimic the integration damage caused by etch and ash. The wafers having the damaged poroud low k dielectric film were sealed with a pore sealing layer that was deposited using a plasma-enhanced atomic layer deposition (PEALD) process on the PECVD tool.

Thickness and refractive index (RI) at 632 nm were measured by a reflectometer (SCI-2000) and an ellipsometer (J. A. Woollam M2000UI). One test to determine if the pore sealing layer was successful was the ellipsometric porosimetry (EP) test. The EP test monitors the wafer color change and ellipsometric spectra shift, which is caused by the toluene vapor diffusing into the unsealed pores. The thickness of the pore sealing layer was analyzed by X-ray reflectivity (XRR), X-ray Photoelectron Spectroscopy (XPS) profiling, and transmission electron microscopy (TEM). A layer of tantalum nitride (TaN) or tantalum oxide (Ta₂O₅) was deposited using ALD and the precursor pentakis(dimethylamino)tantalum and NH₃ or H₂O, respectively, on the wafer. The thickness of TaN or Ta₂O₅ was measured by X-ray fluorescence (XRF). The copper selectivity was performed by repeating the deposition of the pore sealing layer on bare copper (Cu) wafers and measuring the thickness of the pore sealing layer using energy-dispersive X-ray spectroscopy (EDX) and XPS and then comparing the respective thicknesses (e.g., the thickness of the deposited pore sealing layer on the damaged porous low k dielectric film vs. thickness of the deposited pore sealing layer on the bare Cu wafer).

In these experiments, different organosilicon precursors for forming the pore sealing layer were tested under the following conditions. The PDEMS film having an initial dielectric constant of 2.2 films were damaged at 300° C. with 300 W NH₃ plasma for 15 seconds to provide a damaged porous low k film to be used in the following examples. Organosilicon precursor compounds were flowed into the reactor at a rate of 300 milligrams per minute (mg/min) for 1 minute (min) with the throttle valve closed at one or more temperatures ranging from about 200 to about 300° C. The wafers were contacted or soaked in the precursor vapor for 2 min and then the chamber was purged with helium for 2 min. Next, the sample was exposed to a 15 second (sec) Helium (He) plasma at a power setting of 200 Watts (W). The process steps were then repeated for approximately 10 to approximately 30 cycles.

### Example 1: Formation of a Pore Sealing Layer Using Organosilicon Compound Trimethoxymethylsilane Having Formula A

In the present example, Applicants kept the dielectric constant of the pore sealing layer relatively low by using non-nitrogen containing precursors or gases in the process. Applicants also excluded the use of oxygen or other oxidants excluded to prevent the oxidization of copper surface. The damaged porous low k film was contacted with the organosilicon compound trimethoxymethylsilane (C₄H₁₂O₃Si) and treated with a helium plasma. In each cycle, a 200 Watt He plasma was stricken for 15 seconds after the organosilicon precursor compound was flowed into the reactor, allowed to soak onto the surface of the damaged porous low k dielectric film, and then purged. The process was repeated approximately 10 to 30 times to provide the pore sealing layer. The pore sealing layer was deemed effective because no toluene diffused into the damaged porous low k film as evidenced by no color change observed or ellipsometric spectrum shift by the toluene vapor diffusion after 30 cycles treatment. Next, a Ta₂O₅ layer was subsequently deposited onto the wafer, having the pore sealing layer deposited thereupon, with 10 cycles of treatment. After the Ta-containing layer was deposited, there was no indication of Ta diffusion into the pores as tested by X-ray fluorescence (XRF). Therefore, the damaged pores are sealed by forming a pore sealing layer after 10 cycles of contacting with trimethoxymethylsilane and treating with He plasma.

To verify the deposition rate of the pore-sealing layer, the pore-sealing process was conducted for 60 cycles. The film thickness of the pore sealing layer was ˜5.8 nanometers (nm), which indicated that the deposition rate was less than 1 A per cycle. The dielectric constant of the pore sealing layer was about 3.2 to about 3.4, which will not significantly increase k after the pore sealing.

A separate deposition of the pore sealing layer using trimethoxymethylsilane was conducted on Cu substrate as described above. These depositions showed some selectivity on Cu: with 10 cycles treatment on the bare Cu, a less than 3 angstrom thick SiO₂ of pore sealing layer was detected by XPS profiling. Therefore, a 3:1 selectivity on Cu was demonstrated when compared to the pore sealing layer deposited upon the damaged, porous low k dielectric film.

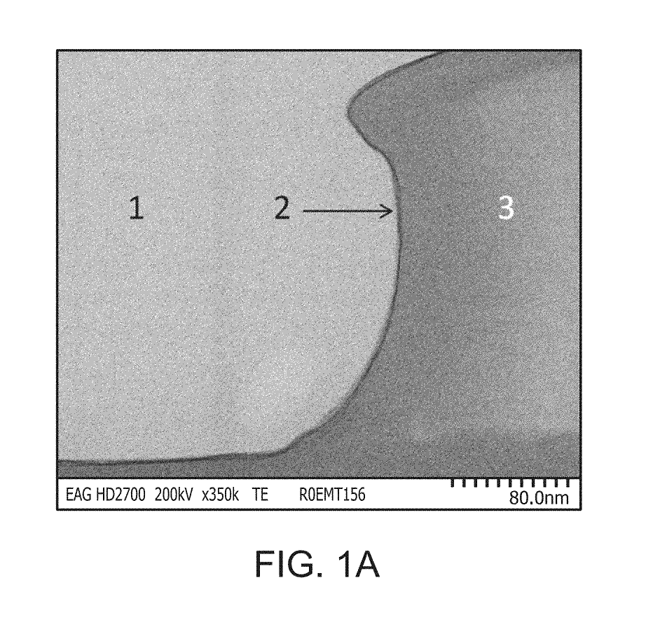

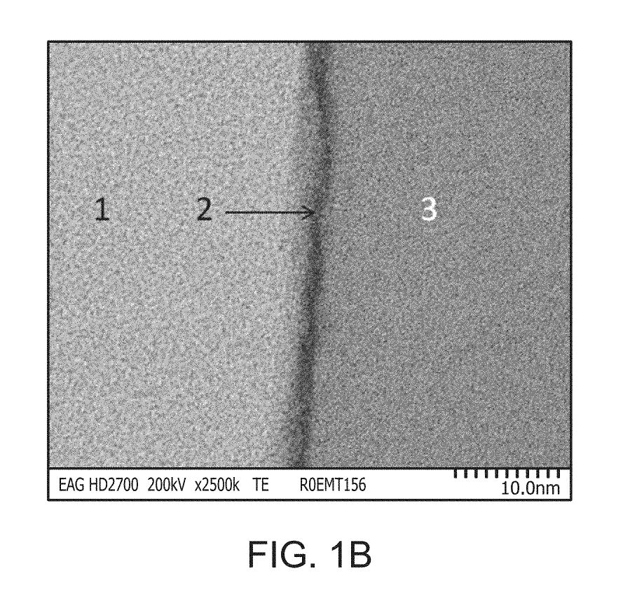

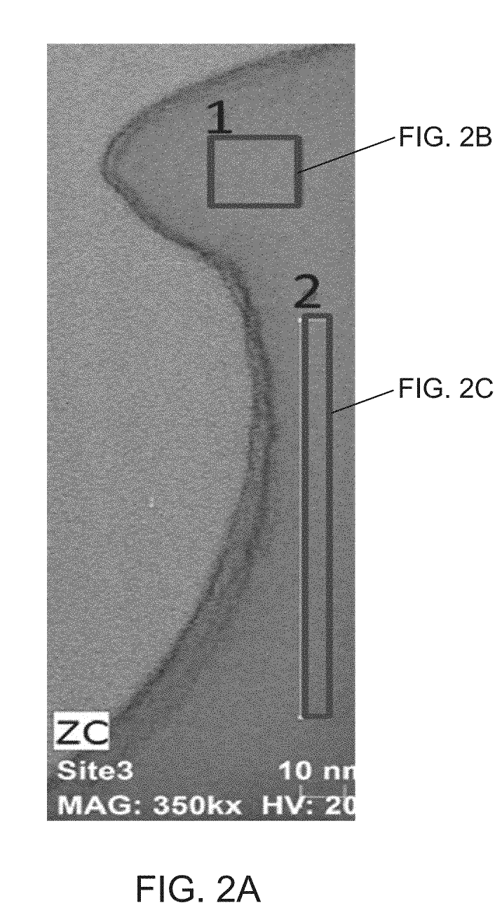

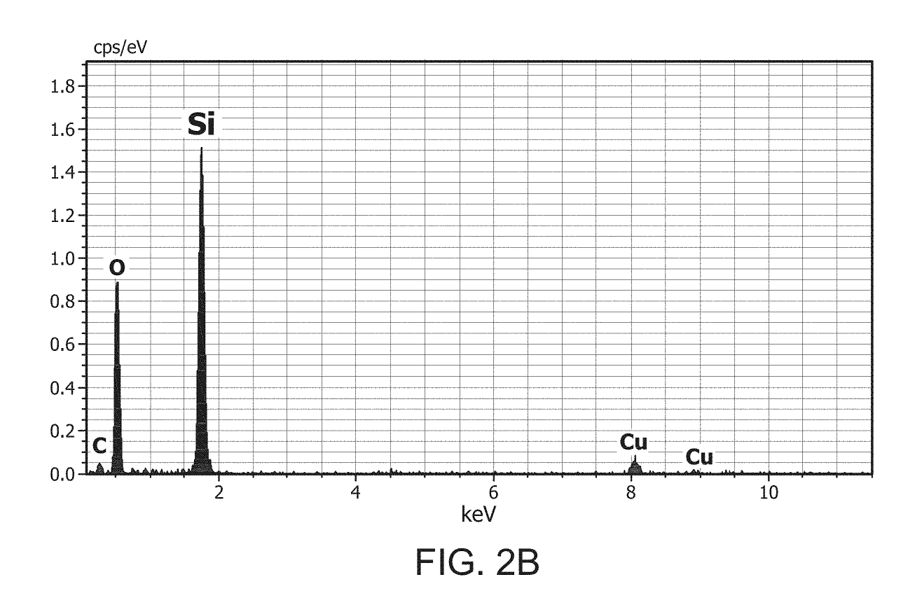

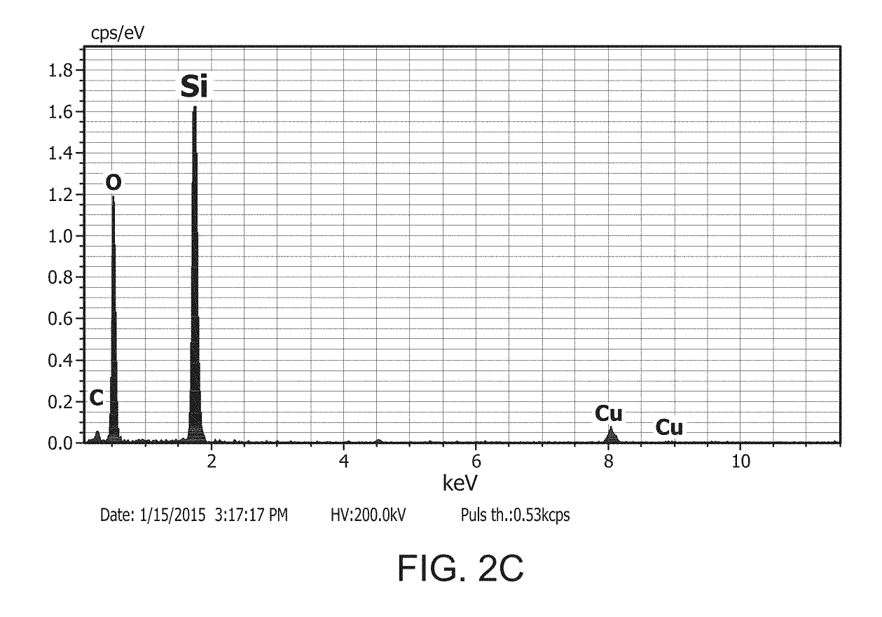

Ten cycles of the deposition of the pore sealing layer (e.g., expose to precursor, purge, and then expose to plasma) was also conducted on patterned OSG low-k films followed by ALD Ta₂O₅ deposition. FIGS. 1a and 1b provide TEM images that show the sidewall of the substrate wherein 1 is a carbon layer, 2 is the Ta₂O₅ layer, and 3 is the porous low k dielectric layer. The pore sealing layer between items 2 and 3 is too thin to be shown on the TEM image. FIGS. 1a and 1b showed good pore-sealing effect without Ta diffusion into the underling low k dielectric film. A clear interface was shown between the Ta₂O₅ layer and the low-k dielectric layer, as shown in FIGS. 1 (a) and (b). FIGS. 2b and 2c provide the EDX obtained from various areas on the sidewall showed is FIG. 2a confirm that there is no detectable Ta in the porous low k dielectric layer 3.

### Example 2: Pore Sealing with Di-isopropyldimethoxysilane (Formula A)

A pore sealing layer was deposited using the organosilicon compound di-isopropyldimethoxysilane (C₈H₂₀OSi) as described above and was found to be suitable for sealing the pores without dramatically raising the dielectric constant compared to undamaged low k films. With up to 30 cycles treatment, the dielectric constant of the low k film only increased from a starting value of 2.2 to a post treatment value of 2.29 (or a change of +0.09). This organosilicon compound was also found to provide relatively good selectivity on a Cu substrate: with 20 cycles treatment, the thickness of pore sealing layer on low k film is about 20 angstroms, whereas the thickness of pore sealing layer on the Cu surface is less than 3.4 A, which showed approximately 6:1 selectivity.

### Example 3: Pore Sealing with Dimethyldiacetoxysilane (Formula C)

A pore sealing layer was deposited using dimethyldiacetoxysilane (C₆H₂O₄Si) as described above. The damaged porous low k film was completely sealed with 10 cycles of contacting with the organosilicon compound and then He plasma treatment The film deposition rate was ˜1.2 A/cycle, which indicates that the pores can be sealed with a pore sealing layer having a thickness of about 1.2 nanometers (nm). Meanwhile, the dielectric constant of the capping layer is less than 4, which is also potential to reduce the k shift. Ta₂O₅ deposition and XRF analysis indicated that the pores were sealed with no Ta diffusion into the pores.

### Example 4: Pore Sealing with 1-methyl-1-ethoxy-1-silacyclopentane (Formula E)

The organosilicon precursor 1-methyl-1-ethoxy-1-silacyclopentane having formula C₇H₆OSi was tested as described above. The NH₃ damaged film can be completely sealed with 10 cycles He or Ar plasma treatment. Ta₂O₅ deposition and XRF analysis indicate that the pores were sealed with no Ta diffusion into the pores. The dynamic SIMS data also showed a dramatic Ta concentration drop at the interface, indicating good pore-sealing effect by 10 cycles of the method described herein.

### Example 5: Pore Sealing with 1,2-Bis(trimethoxysilyl)ethane (Formula F)

Damaged, porous low k dielectric films as described above were contacted by the organosilicon compound 1,2-Bis(trimethoxysilyl)ethane [(CH₃O)₃Si—(CH₂)₂—Si(OCH₃)₃] having formula C₈H₂₂O₆Si₂ were tested using the EP test as described above and passed the EP test with no toluene diffusion. No color change was observed; no ellipsometer shift occurred. XRF analysis also indicated that there was no Ta diffusion into the pores after 10 cycles treatment by 1,2-Bis(trimethoxysilyl)ethane.

The foregoing description is intended primarily for purposes of illustration. Although the invention has been shown and described with respect to an exemplary embodiment thereof, it should be understood by those skilled in the art that the foregoing and various other changes, omissions, and additions in the form and detail thereof may be made therein without departing from the spirit and scope of the invention.

We claim:

1. A method for forming a pore sealing layer, the method comprising the steps of:
a. providing a substrate having a porous low dielectric constant layer in a reactor;
b. contacting the substrate with at least one organosilicon compound having the structure of Formulae E: 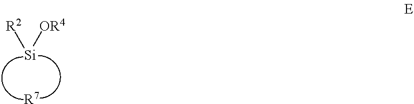
wherein R² is selected from the group consisting of a hydrogen atom, a C₁ to C₁₀ linear alkyl group, a C₃ to C₁₀ branched alkyl group, a C₃ to C₁₀ cyclic alkyl group, a C₅ to C₁₂ aryl group, a C₂ to C₁₀ linear or branched alkenyl group, and a C₂ to C₁₀ linear or branched alkynyl group; R⁴ is selected from the group consisting of a C₁ to C₁₀ linear alkyl group, a C₃ to C₁₀ branched alkyl group, a C₃ to C₁₀ cyclic alkyl group, a C₃ to C₁₀ linear or branched alkenyl group, a C₃ to C₁₀ linear or branched alkynyl group, and a C₅-C₁₂ aryl group; and R⁷ is a C₃ to C₁₀ alkyl di-radical which forms a four-membered, five-membered, or six-membered cyclic ring with the Si atom, to provide an absorbed organosilicon compound on at least a portion of a surface of the porous low dielectric constant layer;
c. purging the reactor with a purge gas;
d. introducing a plasma into the reactor to react with absorbed organosilicon compound, and
e. purging the reactor with a purge gas,
wherein steps b through e are repeated until a desired thickness of the pore sealing layer is formed on the surface and provides a sealed dielectric constant layer.

2. The method of claim 1 wherein the at least one organosilicon compound comprises the compound having Formula E and is selected from the group consisting of 1-methyl-1-methoxy-1-silacyclopentane, 1-methyl-1-ethoxy-1-silacyclopentane, 1-methyl-1-iso-propoxy-1-silacyclopentane, 1-methyl-1-n-propoxy-1-silacyclopentane, 1-methyl-1-n-butoxy-1-silacyclopentane, 1-methyl-1-sec-butoxy-1-silacyclopentane, 1-methyl-1-iso-butoxy-1-silacyclopentane, 1-methyl-1-tert-butoxy-1-silacyclopentane, 1-methoxy-1-silacyclopentane, 1-ethoxy-1-silacyclopentane, 1-methyl-1-methoxy-1-silacyclobutane, 1-methyl-1-ethoxy-1-silacyclobutane, 1-methoxy-1-silacyclobutane, and 1-ethoxy-1-silacyclobutane.

3. The method of claim 1 wherein the thickness of the pore sealing layer is about 5 nanometers or less.

4. The method of claim 1 wherein the thickness of the pore sealing layer is about 3 nanometers or less.

5. The method of claim 1 wherein the thickness of the pore sealing layer is about 1 nanometers or less.

6. The method of claim 1 wherein the porous low dielectric constant layer has a first dielectric constant and the sealed low dielectric constant layer has a second dielectric constant and a difference between the first dielectric constant and the second dielectric constant is 0.5 or less.

7. The method of claim 6 wherein the difference is 0.4 or less.

8. The method of claim 6 wherein the difference is 0.2 or less.

9. The method of claim 1 wherein the porous low dielectric constant layer further comprises metal and wherein a first deposition rate of the pore sealing layer on the porous low dielectric film and a second deposition rate of the pore sealing layer on the metal is from 2 times greater to 10 times greater.
